(19) United States
(12) Patent Application Publication
(10) Pub. No.: US 2010/0097842 A1
(43) Pub. Date: Apr. 22, 2010

(54) RESISTANCE VARIABLE MEMORY DEVICE PROGRAMMING MULTI-BIT DATA

(75) Inventor: Youngnam HWANG, Hwaseong-si (KR)

Correspondence Address: VOLENTINE & WHITT PLLC, ONE FREEDOM SQUARE, 11951 FREEDOM DRIVE SUITE 1260, RESTON, VA, 20190, US

(73) Assignee: SAMSUNG ELECTRONICS CO., LTD., Suwon-si (KR)

(21) Appl. No.: 12/555,831

(22) Filed: Sep. 9, 2009

(30) Foreign Application Priority Data
Oct. 17, 2008 (KR) 10-2008-0102044

(51) Int. Cl. G11C 11/00

(52) U.S. Cl. 365/148; 365/163

(57) ABSTRACT

A phase change memory device is provided to simultaneously program multi-bit data. The phase change memory device includes a memory cell array in which multi-bit data is stored, a buffer circuit storing a lower bit and an upper bit of the multi-bit data, a write driver applying program current to the memory cell array, and a control logic controlling the write driver to simultaneously program the multi-bit data.

### CROSS-REFERENCE TO RELATED APPLICATION

A claim of priority under 35 U.S.C § 119 is made to Korean Patent Application No. 10-2008-0102044, filed on Oct. 17, 2008, the entirety of which is herein incorporated by reference.

### BACKGROUND

The inventive concepts described herein are generally related to resistance variable memory devices and, more specifically to a resistance variable memory device programming multi-bit data.

Semiconductor memory devices are storage devices that contain data therein and allow the stored data to be read therefrom. Semiconductor memory devices may be classified into random access memory (RAM) devices and read only memory (ROM) devices. ROM devices are nonvolatile memory devices which retain stored data even if power supply thereto is interrupted. Examples of ROM devices are programmable ROM (PROM), erasable PROM (EPROM), electrically EPROM (EEPROM), and flash memories. Flash memories are categorized into NAND-type flash memory devices and NOR-type flash memory devices. RAM devices are volatile memory devices which lose stored data when power supply thereto is interrupted. Examples of RAM devices are dynamic RAM (DRAM) and static RAM (SRAM).

Conventional semiconductor memory devices may use nonvolatile materials instead of capacitors in DRAM. Examples of conventional semiconductor memory devices using nonvolatile materials instead of capacitors include ferroelectric RAM (FRAM), magnetic RAM (MRAM) using tunneling magneto-resistive (TMR) films, phase change memory devices using chalcogenide alloys, and the like. In particular, a phase change memory device is a nonvolatile memory device using phase change, i.e., resistance change according to temperature variation. A phase change memory device may be advantageous as having a simpler fabrication process. Accordingly, a memory having a larger capacity may be embodied with lower cost.

A phase change memory device includes a write driver circuit to supply program current to a phase change material (GST) during a program operation. The write driver circuit supplies program current, i.e., set current or reset current to a memory cell by using an external power supply voltage (e.g., 2.5 volt or higher). It is noted that the set current is current for transforming a phase change material (GST) to a set state and the reset current is current for transforming the phase change material (GST) to a reset state. A phase change memory device performs a program verify operation during a program operation to improve reliability of programmed data. In general, a phase change memory device performs a program operation and a program verify operation while increasing program current step by step. The program operation and the program verify operation are collectively called a program loop operation.

### SUMMARY

Embodiments of the inventive concept are generally related to providing a resistance variable memory device and a memory system including the same. In some embodiments, the resistance variable memory device may include a memory cell array in which multi-bit data is stored, a buffer circuit storing a lower bit and an upper bit of the multi-bit data, a write driver applying program current to the memory cell array, and a control logic controlling the write driver to simultaneously program the multi-bit data.

In some embodiments, the memory system may include a central processing unit (CPU), the above-described resistance variable memory device which operates under control of the CPU, and an interface device connecting the CPU and the resistance variable memory device with each other.

### BRIEF DESCRIPTION OF THE DRAWINGS

Embodiments of the inventive concept will become apparent from the following description with reference to the accompanying drawings, in which:

FIG. 1 is a block diagram of a resistance variable memory device according to embodiments of the inventive concept;

FIG. 2 illustrates a physical phase change memory cell;

FIG. 3 illustrates 2 bits logically stored in the physical phase change memory cell illustrated in FIG. 2;

FIG. 4 is a graph illustrating a program operation of a phase change memory cell;

FIG. 5 is a flowchart illustrating a method of simultaneously programming multi-bit data according to embodiments of the inventive concept;

FIG. 6 is a flowchart illustrating a read method according to embodiments of the inventive concept;

FIG. 7 is a block diagram of a phase change memory device according to other embodiments of the inventive concept;

FIG. 8 is a timing diagram illustrating a program operation and a verify operation of the phase change memory device shown in FIG. 7; and

FIG. 9 is a block diagram of a mobile electronic system including a phase change memory device according to embodiments of the inventive concept.

### DETAILED DESCRIPTION OF THE EMBODIMENTS

The embodiments of the inventive concept will now be described more fully hereinafter with reference to the accompanying drawings, in which embodiments of the inventive concept are shown. The inventive concept however may be embodied in many different forms and should not be construed as limited to the embodiments set forth herein. Rather, these embodiments are provided so that this disclosure will be thorough and complete, and will fully convey the scope of the inventive concept to those skilled in the art. Like numbers refer to like elements throughout.

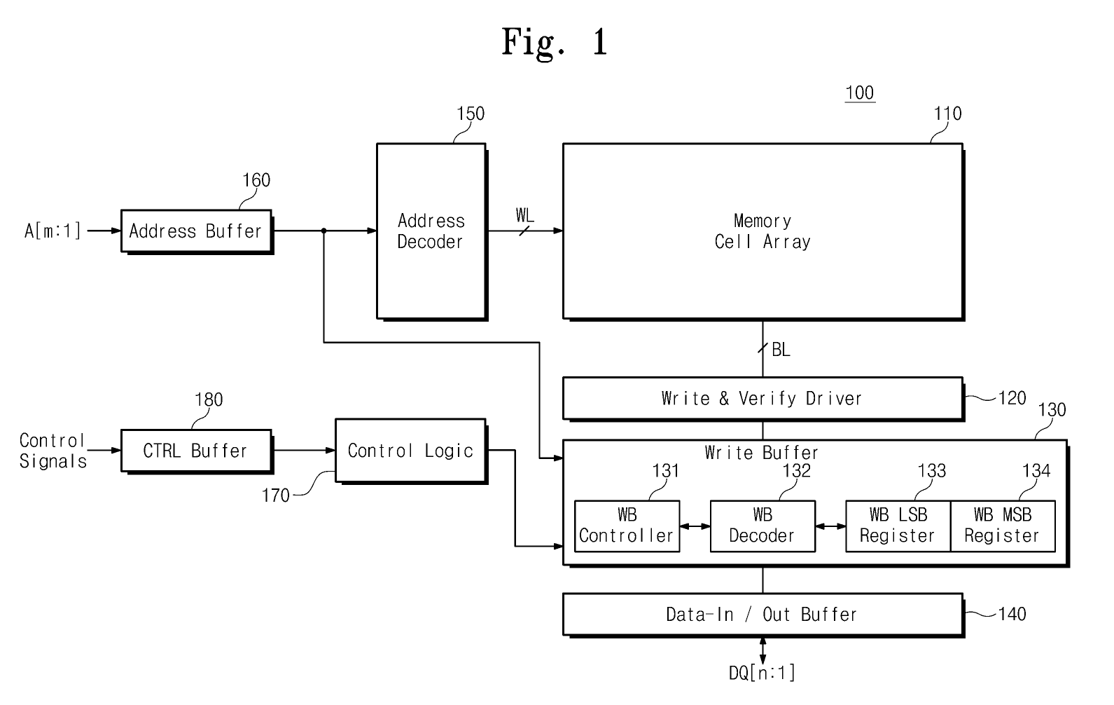

FIG. 1 is a block diagram of a resistance variable memory device 100 according to embodiments of the inventive concept. The resistance variable memory device 100 includes a memory cell array 110, a write driver 120, a write buffer circuit 130, a data input/output buffer 140, an address decoder 150, an address buffer 160, a control logic 170, and a control buffer circuit 180. The memory cell array 110 includes a plurality of memory cells (not shown).

A phase change memory device may be a resistance variable memory device according to some embodiments of the inventive concept. Therefore, each memory cell includes a memory element and a select element. The memory element contains a phase change material (GST), and the select element is embodied with an NMOS transistor or a diode. A phase change material, such as GeSbTe (GST), is a variable resistor having resistance that varies with temperature. The phase change material may have one of two stable states (i.e., a crystal state or an amorphous state) according to temperature. The phase change material changes into a crystal state or an amorphous state according to current supplied through a bitline BL. Programming data of a phase change memory device takes advantage of the above characteristic of the phase change material.

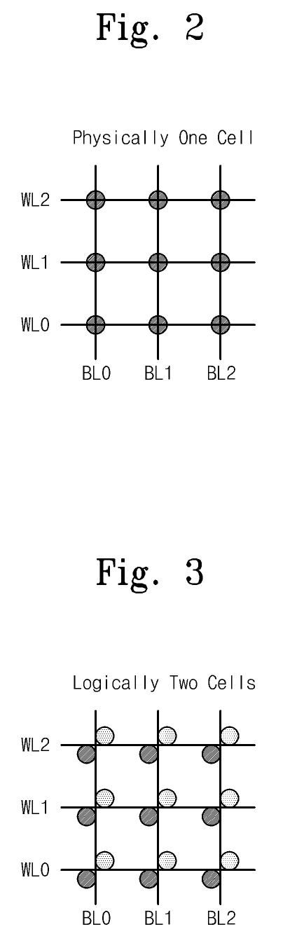

While one bit is physically stored in a phase change memory cell (see FIG. 2), two bits may be logically stored in the phase change memory cell shown in FIG. 2 (see FIG. 3). Moreover, the phase change memory cell may be configured to store multi-bit data over two bits in number.

TABLE 1

| Resistance | MSB | LSB |
|---|---|---|
| R00 | 0 | 0 |
| R01 | 0 | 1 |
| R10 | 1 | 0 |
| R11 | 1 | 1 |

As shown TABLE 1, one phase memory cell physically has four states according to resistance values. That is, the most significant bit (MSB) and the least significant bit (LSB) of a phase change memory cell having a resistance value “R00” are 0 and 0, respectively; the MSB and LSB of a phase change memory cell having a resistance value “R01” are 0 and 1, respectively; the MSB and LSB of a phase change memory cell having a resistance value having “R10” are 1 and 0, respectively; and the MSB and LSB of a phase change memory cell having a resistance value “R11” are 1 and 1, respectively.

The write and verify driver 120 receives a program pulse, a verify pulse, and data, and supplies program current and verify current to the memory cell array 110. The program pulse includes a set pulse and a reset pulse. The write and verify driver 120 supplies the cell set current in response to a set pulse when data ‘0’ is input and supplies the reset current in response to a reset pulse when data ‘1’ is input.

The address buffer circuit 160 transmits an address signal A<m:1> to the write buffer circuit 130 and the address decoder 150 after temporarily storing the address signal A<m:1>. The address decoder 150 provides the address signal A<m:1> to the memory cell array 110.

The control buffer circuit 180 transfers a control signal to the control logic 170 after temporarily storing the control signal.

The data input/output circuit 140 outputs data DQ<n:1> transferred from the write buffer circuit 130 or transfers externally transferred data DQ<n:1>.

The control logic 170 controls the write buffer circuit 130 in response to the control signal transferred from the control buffer circuit 180.

The write buffer circuit 130 outputs data to be written through the write and verify driver 120 after temporarily storing the data. The write buffer circuit 130 is used as a data cache. That is, in the case that data accessed from the control logic 170 is stored in the write buffer circuit 130, the write buffer circuit 130 outputs the stored data through the data input/output buffer circuit 140.

The write buffer circuit 130 includes a write buffer controller 131, a write buffer decoder 132, a write buffer LSB register 133, and a write buffer MSB register 134.

The write buffer controller 131 determines whether externally accessed data is stored in the memory cell array or the write buffer circuit 130. When the externally accessed data is stored in the write buffer circuit 130, the write buffer controller 131 outputs data mapped through the write buffer decoder 132 to the data input/output buffer 140. The write buffer controller 131 maps data accessed from the write buffer decoder 132 with corresponding data.

The write buffer LSB register 133 stores first data among data transferred from the data input/output buffer 140, and the write buffer MSB register 134 stores second data among the data transferred from the data input/output buffer 140.

Two bits are stored in a phase change memory cell according to embodiments of the inventive concept.

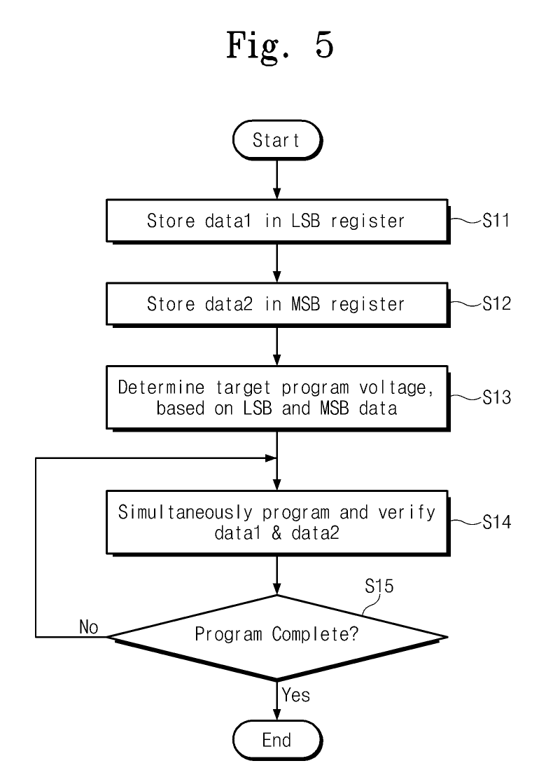

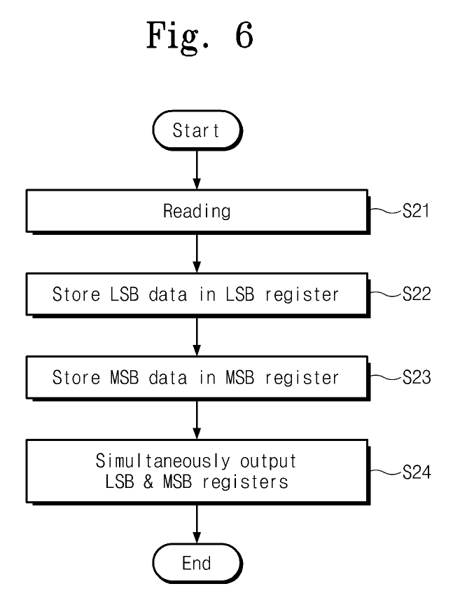

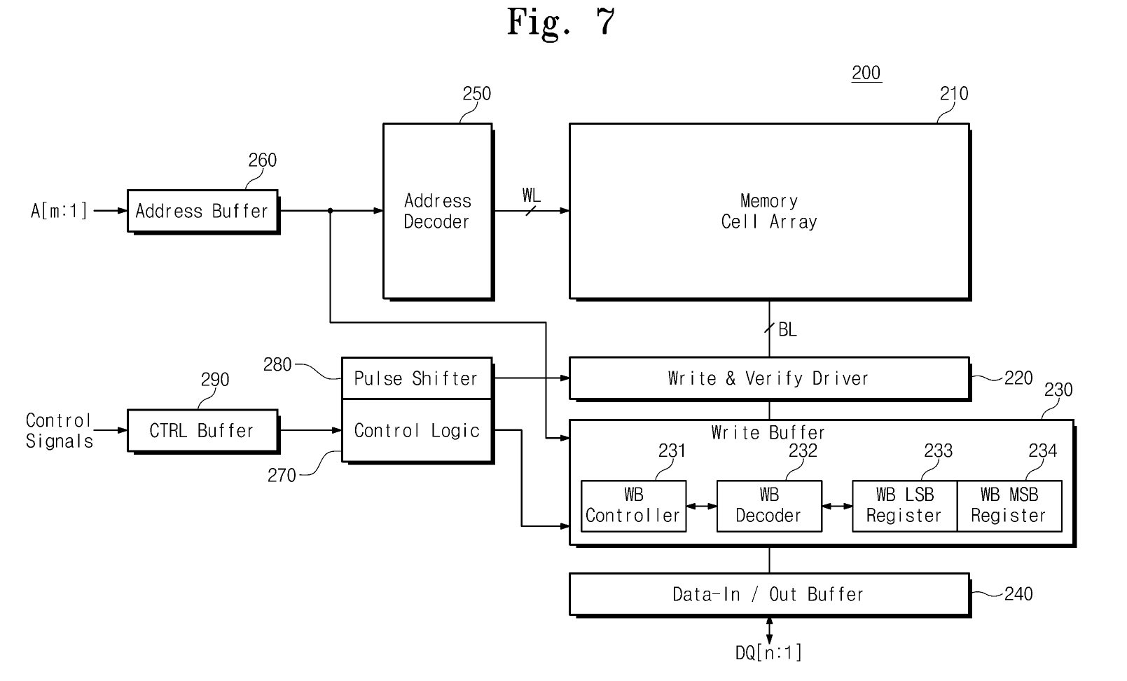

In a resistance variable memory device according to some embodiments of the inventive concept, first input data is stored in the write buffer LSB register 133 and second input data is stored in the write buffer MSB register 134. In addition, the data stored in the write buffer LSB register 133 and the data stored in the write buffer MSB register 134 are simultaneously programmed in one phase change memory cell. A program method and a read method of multi-bit data according to the inventive concept will be described in detail with reference to FIG. 5 and FIG. 6, respectively.

While a typical flash memory cell is programmed twice to write two bits, a memory cell according to embodiments of the inventive concept is programmed once to write two bits.

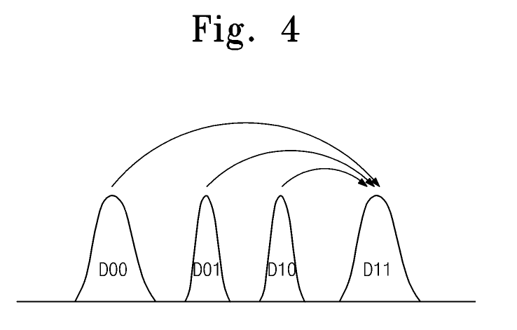

FIG. 4 is a graph illustrating a program operation of a phase change memory cell. The program operation includes time of programming a phase change memory cell of a D00 state into a D11 state, time of programming a phase change memory cell of a D01 state into the D11 state, and time of programming a phase change memory cell of a D10 state into the D11 state, which are equal to one another. Irrespective of current states of the phase change memory cells, write current is equivalently supplied to the phase change memory cells. A resistance variable memory device according to embodiments of the inventive concept does not suffer from an increase of write disturbance even though two bits are simultaneously programmed. That is, the time taken to program one bit and the time taken to program two bits are equal to each other.

FIG. 5 is a flowchart illustrating a method of programming multi-bit data according to some embodiments of the inventive concept.

Referring to FIGS. 1 and 5, the method includes a step S11 at which first data is stored in the write buffer LSB register 133, a step S12 at which second data is stored in the write buffer MSB register 134, a step S13 at which a target program voltage is decided based on the first data and the second data, a step S14 at which the data stored in the write buffer LSB register 133 and the data stored in the write buffer MSB register 134 are simultaneously programmed and verified, and a step S15 at which it is determined whether the program operation is completed. When the program operation is completed, this routine comes to an end. On the other hand, when the program operation is not completed, this routine goes to the step S14.

FIG. 6 is a flowchart illustrating a read method according to embodiments of the inventive concept.

Referring to FIGS. 1 and 6, the read method includes a step S21 at which data stored in any memory cell of a memory cell array 110 is read out, a step S22 at which LSB data is stored in the write buffer LSB register 133, a step S23 at which MSB data is stored in the write buffer MSB register 134, and a step S24 at which the data stored in the write buffer LSB register 133 and the data stored in the write buffer MSB register 134 are simultaneously output.

According to the above read method, data stored in any memory cell of the memory cell array 110 are read out and the read-out data are sequentially output.

As a result, a resistance variable memory device according to embodiments of the present invention programs multi-bit data simultaneously to reduce program time.

FIG. 7 is a block diagram of a resistance variable memory device according to other embodiments of the inventive concept. Except for pulse shifter 280, the resistance variable memory device 100 shown in FIG. 7 is identical to that shown in FIG. 1. Therefore, duplicate explanation will be omitted herein for the sake of brevity. Referring to FIG. 7, the pulse shifter 280 provides a plurality of program pulses and verify pulses to a write and verify driver 220 in response to the control of a control logic 270. Before providing the program and verify pulses, the pulse shifter 280 shifts each of the program and verify pulses to prevent them from overlapping each other.

A typical phase change memory device does not program 16-bit data DQ<16:0> simultaneously, in order to decrease program currents simultaneously applied during a program operation. For example, 16-bit data are sequentially programmed eight times in 2-bit units or four times in 4-bit units, which are called “×2 input/output method” and “×4 input/output method”, respectively.

The resistance variable memory device 200 performs a program and verify operation. During the program and verify operation, input 16-bit data DQ<16:0> are programmed in parallel. That is, according to embodiments of the inventive concept, program pulses are regulated by the pulse shifter 280 so as not to overlap each other. Thus, the resistance variable memory device 200 may exhibit low current peak during a simultaneous program operation and perform a high-speed program operation.

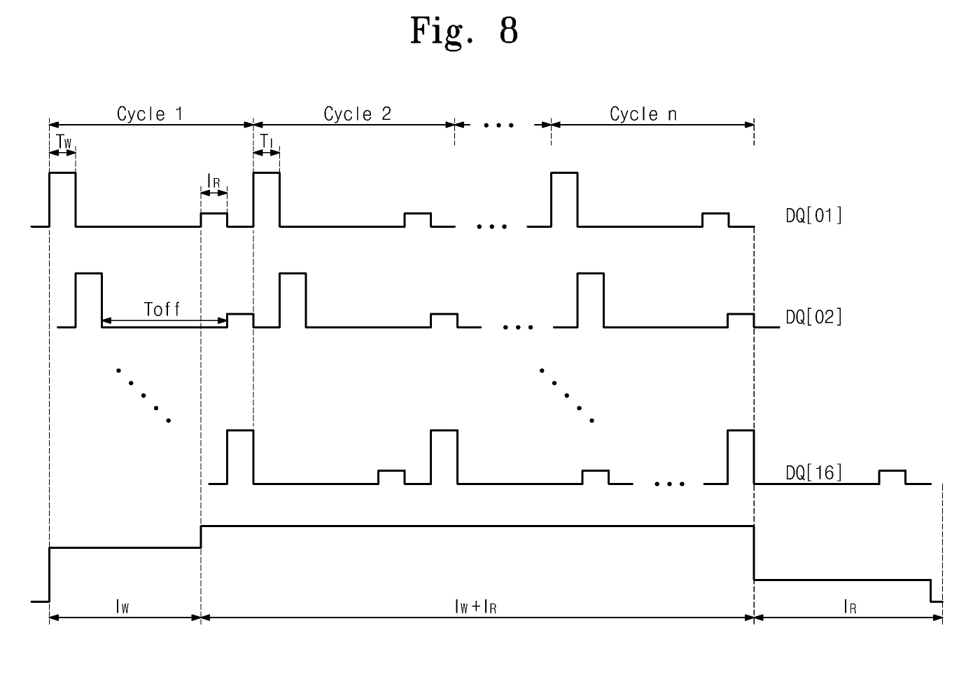

The program and verify operation of the resistance variable memory device 200 shown in FIG. 7 will now be described below by reference to a timing diagram in FIG. 8. Timings of first to n^{th} cycles are shown in FIG. 8. Each of the cycles includes program time T_{w}, off time T_{off}, verify time T_{R}, and initialization time T₁.

The program time T_{w}, is time at which program current corresponding to a program pulse is applied to a phase change material (GST) of a memory cell. The off time T_{off} is time required for changing the phase change material to have resistance of a predetermined level through a program operation. In this embodiment, the off time T_{off} is 500 nanoseconds. The verify time T_{R} is time to check whether the program operation is normally completed. When target data is not written during a previous program operation, the next program operation is performed by increasing or decreasing a program pulse. The initialization time T₁ is time required for preparing a program operation of the next cycle after a verify operation of a previous cycle is completed.

Referring to FIGS. 7 and 8, the pulse shifter 280 shifts a plurality of program pulses step by step to prevent them from overlapping each other. Accordingly, the program and verify operation of the resistance variable memory device 200 is performed to program input 16-bit data DQ<16:0> in parallel.

As illustrated in FIG. 8, the peak of current consumed during the program and verify operation of the resistance variable memory device 200 is equal to the sum of program current I_{W} and verify current I_{R}.

The resistance variable memory device 200 according to other embodiments of the inventive concept regulates program pulses to prevent them from overlapping each other. Thus, the resistance variable memory device 200 may exhibit low current peak during a simultaneous program operation and perform a high-speed program operation.

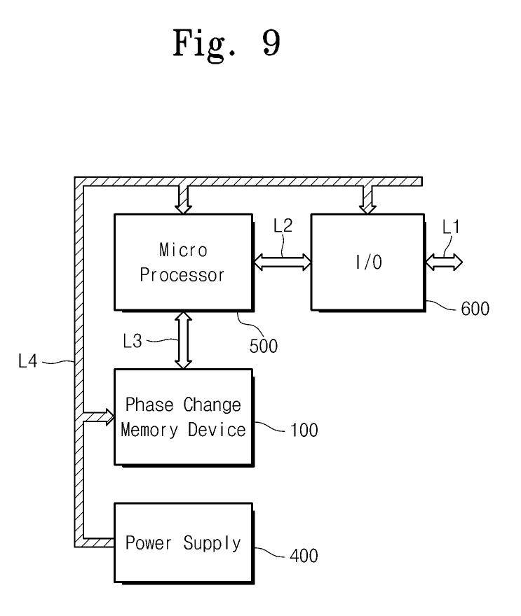

FIG. 9 is a block diagram of a mobile electronic system including a phase change memory device according to embodiments of the inventive concept. A phase change memory device 100 is a resistance variable memory device connected to a microprocessor 500 through a bus line L3, and functions as a main memory of the mobile electronic system. A battery 400 supplies power to the microprocessor 500, an input/output device 600, and the resistance variable memory device 100 through a power line L4.

In the case where received data is provided to the input/output device 600, the microprocessor 500 receives the data through a line L2 and processes the same. Afterwards, the microprocessor 500 applies the received or processed data to the resistance variable memory device 100. The resistance variable memory device 100 stores the data applied through the bus line L3 in a memory cell. The data stored in the memory cell is read out by the microprocessor 500 and output to the outside through the input/output device 600.

When the power of the battery 400 is not supplied to the power line L4, the data stored in the memory cell of the resistance variable memory device 100 is not erased due to the characteristics of a phase change material. This is because the resistance variable memory device 100 is a nonvolatile memory device, unlike a DRAM device. Besides, the resistance variable memory device 100 is advantageous as having a higher operation speed and lower power consumption than other memory devices.

Although the inventive concepts have been described in connection with the disclosed embodiments illustrated in the accompanying drawings, the inventive concepts not limited thereto. It will be apparent to those skilled in the art that various substitutions, modifications and changes may be made without departing from the scope and spirit of the inventive concept.

What is claimed is:

1. A resistance variable memory device comprising:
a memory cell array in which multi-bit data is stored;
a buffer circuit storing a lower bit and an upper bit of the multi-bit data;
a write driver applying program current to the memory cell array; and
a control logic controlling the write driver to simultaneously program the multi-bit.

2. The resistance variable memory device of claim 1, wherein the buffer circuit comprises:
an LSB register storing a lower bit of the multi-bit data; and
an MSB register storing an upper bit of the multi-bit data.

3. The resistance variable memory device of claim 1, further comprising:
a pulse shifter shifting a program pulse to generate a plurality of program pulses,
wherein the control logic provides the program pulses generated by the pulse shifter to the write driver to perform a program operation in parallel.

4. The resistance variable memory device of claim 3, wherein the write driver receives the shifted program pulses to supply program current corresponding to the shifted program pulses to memory cells of the memory cell array.

5. The resistance variable memory device of claim 4, wherein the program current increases step by step during the program operation.

6. The resistance variable memory device of claim 4, wherein the program shifter shifts a verify pulse to generate a plurality of shifted verify pulses.

7. The resistance variable memory device of claim 6, wherein the shifted program pulses and the shifted verify pulses do not overlap each other.

8. The resistance variable memory device of claim 7, wherein the control logic provides the shifted verify pulses generated by the pulse shifter to the write driver to perform a verify operation following the program operation.

9. The resistance variable memory device of claim 1, wherein the memory cell array includes a plurality of memory cells each including a memory element configured to store multi-bit data.

10. A memory system comprising:
a central processing unit;
a resistance variable memory device operating under control of the central processing unit; and
an interface device connecting the central processing unit and the resistance variable memory device with each other,
wherein the resistance variable memory device includes
a memory cell array in which multi-bit data is stored,
a buffer circuit storing a lower bit and an upper bit of the multi-bit data,
a write driver applying program current to the memory cell array, and
a control logic controlling the write driver to simultaneously program the multi-bit data.

11. A resistance value memory device comprising:
a memory cell array having a plurality of resistance variable memory cells;
a write buffer including a first resistor that temporarily stores a first bit of input multi-bit data and a second register that temporarily stores a second bit of the multi-bit data;
a write driver that applies program current to the memory cell array; and
control logic that controls the write driver to simultaneously program the first bit and the second bit of the multi-bit data temporarily stored in the first and second registers into a corresponding one of the resistance variable memory cells.
